(19) United States
(12) Patent Application Publication
(10) Pub. No.: US 2023/0327031 A1
(43) Pub. Date: Oct. 12, 2023

(54) SOLAR CELL MANUFACTURING METHOD

(71) Applicant: KOREA UNIVERSITY RESEARCH AND BUSINESS FOUNDATION, Seoul (KR)

(72) Inventors: Hae-Seok LEE, Seoul (KR); Donghwan KIM, Yangpyeong-gun Gyeonggi-do (KR); Yoonmook KANG, Seoul (KR); Dongjin CHOI, Seoul (KR); Soohyun BAE, Seoul (KR); HyunJung PARK, Seoul (KR); Changhyun LEE, Seoul (KR); Hyebin HAN, Seoul (KR)

(21) Appl. No.: 18/025,283

(22) PCT Filed: Jun. 11, 2021
(86) PCT No.: PCT/KR2021/007334

§ 371 Date: Mar. 8, 2023

(30) Foreign Application Priority Data
Jul. 8, 2020 (KR) 10-2020-0084047

(51) Int. Cl. H01L 31/0224

(52) U.S. Cl. CPC H01L 31/022425

(57) ABSTRACT

The present invention provides a method for manufacturing a solar cell by forming an electrode on a semiconductor substrate, comprising: a first printing step of printing a first paste on the semiconductor substrate; a first sintering step of sintering the first paste to form a first electrode layer; a second printing step of printing a second paste on the first electrode layer; and a second sintering step of sintering the second paste to form a second electrode layer.

### TECHNICAL FIELD

The present disclosure relates to a method for manufacturing a solar cell.

The present disclosure was derived from a study performed as a measure of an energy technology development business (project ID number: 20163010012570, study management institute: Korea Institute of Energy Technology Evaluation and Planning, study title: Development of Nano Patten Rear Electrode and High-efficiency Thin Film Solar Cell using Solution Process based 1 Micrometer or less Ultra-Thin Film CIGS, Major Institute: Korea Institute of Science and Technology, study period: Dec. 1, 2016 to Sep. 30, 2020, and contribution ratio: 1/2) of Ministry of Trade, Industry and Energy.

The present disclosure was derived from a study performed as a measure of an energy technology development business (project ID number: 20193020010370, study management institute: Korea Institute of Energy Technology Evaluation and Planning, study title: Development of Integral Low-Illumination Intensity Organic Solar Cell-Storage Medium Smart Module for Driving Sensor, Major Institute: Kyung Hee University, study period: Oct. 1, 2019 to Sep. 30, 2022, and contribution ratio: 1/2) of Ministry of Trade, Industry and Energy.

Meanwhile, in all aspects of the present disclosure, there is no property in fortune of Korean government.

### BACKGROUND ART

In recent years, interests on alternative energy that is to replace existing energy resources, such as petroleum or coals, as depletion of the existing energy resources is expected have been increased. Among them, solar cells are spot-lighted as next-generation batteries for directly changing solar energy to electric energy by using semiconductor elements.

The solar cells are devices that convert light energy to electric energy by using a photovoltaic effect, and may be classified into silicon solar cells, thin film type solar cells, pigment-adaptive solar cells, and organic polymer solar cells according to constituent materials thereof, and among them, the silicon solar cells are mainly used. According to the solar cells, it is very important to increase a conversion efficiency related to a ratio of converting input solar light to electric energy.

Meanwhile, a front electrode of a silicon solar cell is formed by screen-printing a paste having fluidity once, and the formed front electrode hardly has a sufficient aspect ratio, and thus, a fill factor of the solar cell may decrease as a resistance of the front electrode increases.

### DETAILED DESCRIPTION OF THE INVENTION

### Technical Problem

As aspect of the present disclosure provides a method for manufacturing a solar cell, by which electrical characteristics of an electrode may be maintained and enhanced by adjusting a heat treatment process and a heat treatment atmosphere at a high temperature when the electrode is formed by using double printing.

Meanwhile, the technical objectives that are to be achieved in the present disclosure are not limited to the above-mentioned technical objectives, and other technical objectives may be clearly understood by an ordinary person in the art, to which the present disclosure pertains, from the following description.

### Technical Solution

A method for manufacturing a solar cell by forming electrodes on a semiconductor substrate according to an aspect of the present disclosure includes a first printing operation of printing a first paste on the semiconductor substrate, a first sintering operation of forming a first electrode layer by sintering the first paste, a second printing operation of printing a second paste on the first electrode layer, and a second sintering operation of forming a second electrode layer by sintering the second paste.

Furthermore, the first paste may be an Ag paste, and the second paste may be a Cu (core)-Ag (shell) paste.

Furthermore, the first sintering operation may be performed under an air or oxygen atmosphere, and the second sintering operation may be performed under an inert gas atmosphere.

Furthermore, the first sintering operation may include forming a plurality of Ag crystallites in the first electrode layer.

Furthermore, the second sintering operation may include maintaining the plurality of Ag crystallites formed in the first electrode layer.

Furthermore, the first paste may be printed by using a first screen mask in the first printing operation, the second paste may be printed by using a second screen mask in the second printing operation, only a finger pattern may be formed in the first screen mask, and the finger pattern and a bus bar pattern may be formed in the second screen mask.

Furthermore, an emitter layer and a reflection preventing layer may be formed on the semiconductor substrate, and the first paste may be printed on the emitter layer in the first printing operation.

### Advantageous Effects of the Invention

According to the embodiment of the present disclosure, electrical characteristics of an electrode may be maintained and enhanced by adjusting a heat treatment process and a heat treatment atmosphere at a high temperature when the electrode is formed by using double printing.

Meanwhile, the technical objectives that may be obtained in the present disclosure are not limited to the above-mentioned effects, and other effects may be clearly understood by an ordinary person in the art, to which the present disclosure pertains, from the following description.

### DESCRIPTION OF THE DRAWINGS

FIG. 1 is a perspective view illustrating a solar cell manufactured according to a method for manufacturing a solar cell according to an embodiment of the present disclosure;

FIG. 2 is a cross-sectional view taken along line A-A′ of FIG. 1;

FIG. 3 is an enlarged view of 3 of FIG. 2;

FIG. 4 is a flowchart illustrating a method for manufacturing a solar cell according to an embodiment of the present disclosure;

FIGS. 5 and 6 are sectional views sequentially illustrating a manufacturing process according to a flow of FIG. 4;

FIGS. 7 and 8 are an exemplary view and an electronic microscopic image illustrating characteristics of an electrode manufactured according to an embodiment of the present disclosure;

FIGS. 9 to 14 are exemplary views and electronic microscopic images illustrating characteristics of electrodes manufactured according to comparative examples 1 to 3 of the present disclosure; and

FIG. 15 is a graph depicting IV results of solar cells according to an embodiment, comparative example 1, and comparative example 4 of the present disclosure.

### BEST MODE

Hereinafter, an embodiment of the present disclosure will be described in detail with reference to the accompanying drawings. The embodiment of the present disclosure may be modified into various forms, and it should not be construed that the scope of the present disclosure is limited to the following embodiments. The present embodiment is provided to describe the present disclosure more fully to an ordinary person in the art, to which the present disclosure pertains. Accordingly, shapes of elements in the drawings are exaggerated to emphasize a clearer description.

The configurations of the present disclosure for making solutions for an objective that is to be solved by the present disclosure clear will be described in detail with reference to the accompanying drawings based on a preferred embodiment of the present disclosure, and it is noted that the same reference numerals denote the same components even though they are provided in different drawing and a component in another drawing may be cited if necessary when the corresponding drawing is described.

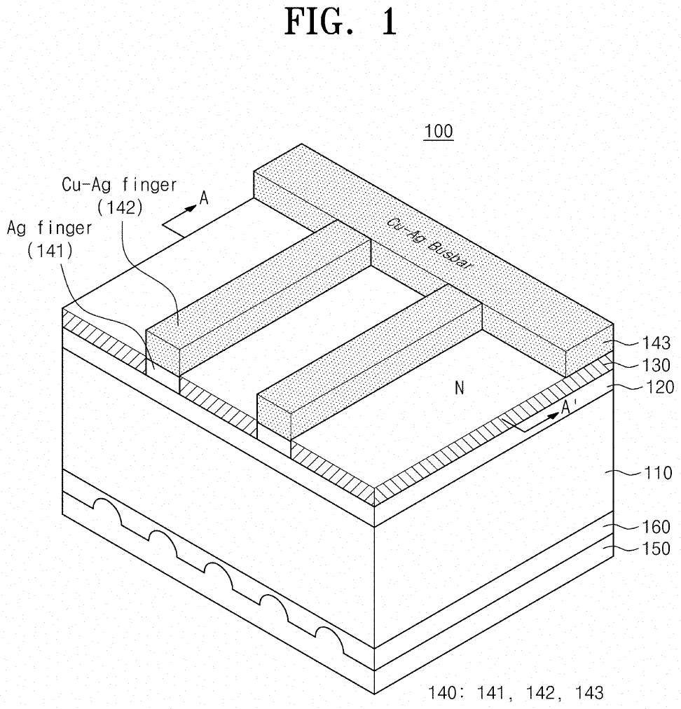

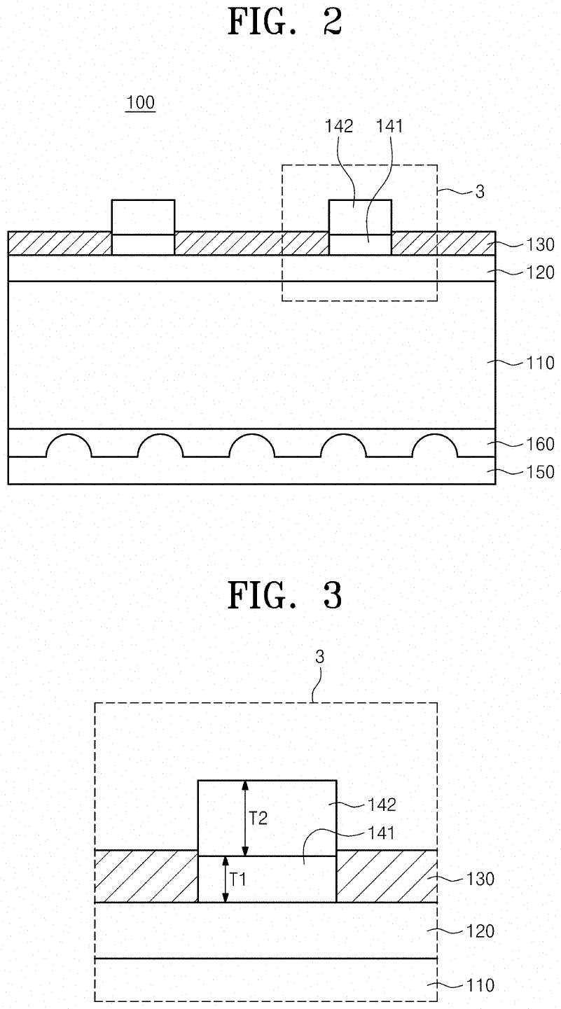

FIG. 1 is a perspective view illustrating a solar cell manufactured according to a method for manufacturing a solar cell according to an embodiment of the present disclosure. FIG. 2 is a cross-sectional view taken along line A-A′ of FIG. 1. FIG. 3 is an enlarged view of 3 of FIG. 2.

First, referring to FIGS. 1 to 3, a solar cell 100 manufactured according to a method for manufacturing a solar cell according to an embodiment of the present disclosure will be described.

First, referring to FIGS. 1 to 3, the solar cell 100 manufactured according to a method for manufacturing a solar cell according to an embodiment of the present disclosure will be described.

The solar cell 100 may include a silicon semiconductor substrate 110, an emitter layer 120 on the substrate 110, a reflection preventing film 130 on the emitter layer 120, a front electrode 140 that passes through the reflection preventing film 130 to be connected to the emitter layer 120, a rear electrode 150, and a rear electric field layer 160.

The substrate 110 may be formed of silicon, and may be doped with impurities, such as B, Ga, and In, which are group 3 elements as P type impurities to be implemented.

The emitter layer 120 may be formed by injecting N type impurities into the P type semiconductor substrate 110.

The emitter layer 120 may be doped with impurities, such as P, As, and Sb, which are group 5 elements as N type impurities. The emitter layer 120 may be formed through a method, such as a diffusion method, a spray method, or a printing method. As an example, the emitter layer 120 may be formed by injecting N type impurities into the P type semiconductor substrate 110.

In this way, when opposite conductive type impurities are doped on the emitter layer 120 and the substrate 110, a P-N junction may be formed on an interface between the emitter layer 120 and the substrate 110, and when light is irradiated to the P-N junction, a photoelectric force may be generated by a photoelectric effect.

The reflection preventing film 130 may be formed on the emitter layer 120 to decrease a reflectance of solar light that is input to a front surface of the substrate 110 and passivate a defect that is present on a surface or a bulk of the emitter layer 120.

The reflection preventing film 130 may be formed through a vacuum deposition method, a chemical vapor deposition method, spin coating, screen printing, or spray coating, but the present disclosure is not limited thereto.

When the reflectance of the solar light decreases, an amount of light that reaches the P-N junction increases, and a short circuit current Isc of the solar cell 100 increases. Furthermore, as the defect that is present in the emitter layer 120 is passivated, a re-bonding site of minor carriers is removed, and an opening voltage Voc of the solar cell 100 increases. In this way, when a short-circuit current and an opening voltage of the solar cell 100 is increased by the reflection preventing film 130, a conversion efficiency of the solar cell 100 may be enhanced correspondingly.

The reflection preventing film 130 may include, for example, a single film or a combination of two or more films selected from the group consisting of a silicon nitride film, a silicon nitride film containing hydrogen, a silicon oxide film, a silicon oxynitride film, MgF2, ZnS, TiO2, and CeO2. may have a multilayer structure.

Meanwhile, although not illustrated in the drawings, one surface of the substrate 110, to which the solar light is input, may have a textured surface. The texturing means forming a pattern having a convexo-concave shape on a surface of the substrate 110, and when the substrate 110 has the textured surface, the emitter layer 120 and the reflection preventing film 130, which are sequentially located on the substrate 110, also may be formed according to a shape of the textured surface. Accordingly, a reflectance of the input solar light may be reduced, and thus an optical loss may be reduced.

The convexo-concave shape may be formed through a process of immersing the substrate 110 with an etching liquid or the like, laser etching, reactive ion etching, and the like, and the convexo-concave shape may have various shapes, such a pyramid shape, a square shape, and a triangular shape.

The front electrode 140 may pass through the reflection preventing film 130 to be connected to the emitter layer 120, and may be formed through a heat treating process after printing the paste for the front electrode 140 containing silver, glass, frit, and the like.

Then, the front electrode 140 is connected to the emitter layer 120 through a fire through phenomenon, in which the reflection preventing film 130 is penetrated by a medium of glass frit while the silver contained in the paste for the front electrode 140 is changed to a liquid state at a high temperature and is crystallized to a solid state again through a heat treating process of the front electrode 140.

The front electrode 140 may include finger lines 141 and 142, and bus bar electrode 143 electrically connected to the finger lines 141 and 142. The finger lines 141 and 142 are configured mainly to collect electrons that are generated in the solar cell 100 and the bus bar electrode 143 is configured such that a ribbon (not illustrated) is attached thereto when a plurality of solar cells 100 are configured in one module, and through this, electrons may be supplied to an outside.

Meanwhile, the finger lines 141 and 142 may include the first electrode layer 141, and the second electrode layer 142 on the first electrode layer 141.

The first electrode layer 141 and the second electrode layer 142 may be formed by performing two screen printing processes as will be described below, and thus, an aspect ratio of the finger lines 141 and 142 may be enhanced and a light reception area of the solar cell 100 may be increased.

Here, because the first electrode layer 141 may be formed through the silver (Ag) paste and the second electrode layer 142 may be formed through the copper (core)-silver (shell) paste, costs for the electrode may be reduced while electrical characteristics thereof are not degraded.

Furthermore, because the second electrode layer 142 located on the first electrode layer 141 hardly requires a necessity for a fire through phenomenon for penetrating the reflection preventing film 130 as compared with the first electrode layer 141, a content of the glass frit contained in the paste for forming the second electrode layer 142 may be not more than a content of the glass frit contained in the paste for forming the first electrode layer 141.

Meanwhile, the first electrode layer 141 may have a first thickness T1, and the second electrode layer 142 may have a second thickness T2 that is larger than the first thickness T1.

Through this, when the finger electrode is formed, an amount of used silver (Ag) paste may be reduced, and thus, manufacturing costs of the solar cell may be reduced.

Meanwhile, the first electrode layer 141 may be printed by using a first screen mask (not illustrated), and the second electrode layer 142 may be printed by using a second screen mask (not illustrated).

Here, the bus bar electrode 143 may be formed together when the second electrode layer 142 is formed, through the copper (core)-silver (shell) paste.

That is, the bus bar electrode 143 may be printed together with the second electrode layer 142 to be formed by using the second screen mask (not illustrated).

The first screen mask may include a plurality of finger patterns (not illustrated) that are opened to form the first electrode layer 141, and the second screen mask may include a plurality of finger patterns (not illustrated) that are opened to form the second electrode layer 142 corresponding to the first electrode layer 141, and a bus bar pattern (not illustrated) that is opened to form the bus bar electrode 143.

Furthermore, the solar cell 100 may include a bus bar part (not illustrated) that is formed on the rear surface of the substrate 110 to be adjacent to the rear electrode 150, in which the rear electric field layer 160 is formed, between the solar cell 100 and the substrate 110, and is connected to a lead wire (not illustrated) for a module.

The rear electrode 150 may be formed by performing a heat treatment after pasting an electrode part paste, to which aluminum, quartz silica, a binder, and the like are added, in an area, in which no bus bar part (not illustrated) is formed. During a heat treatment of the printed rear electrode part paste, the rear electric field layer 160 may be formed on a border surface of the rear electrode part and the substrate 100 by diffusing aluminum that is an electrode material through the rear surface of the substrate 110.

The rear electric field layer 160 may prevent the carriers from flowing to the rear surface of the substrate 110 to be bonded again, and when the re-bonding of the carriers are prevented, an opening voltage may increase and thus an efficiency of the solar cell 100 may be enhanced.

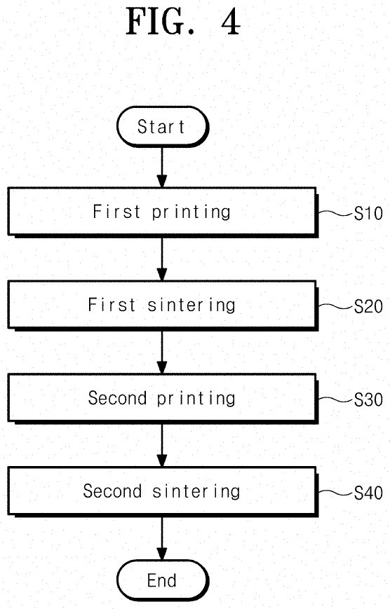

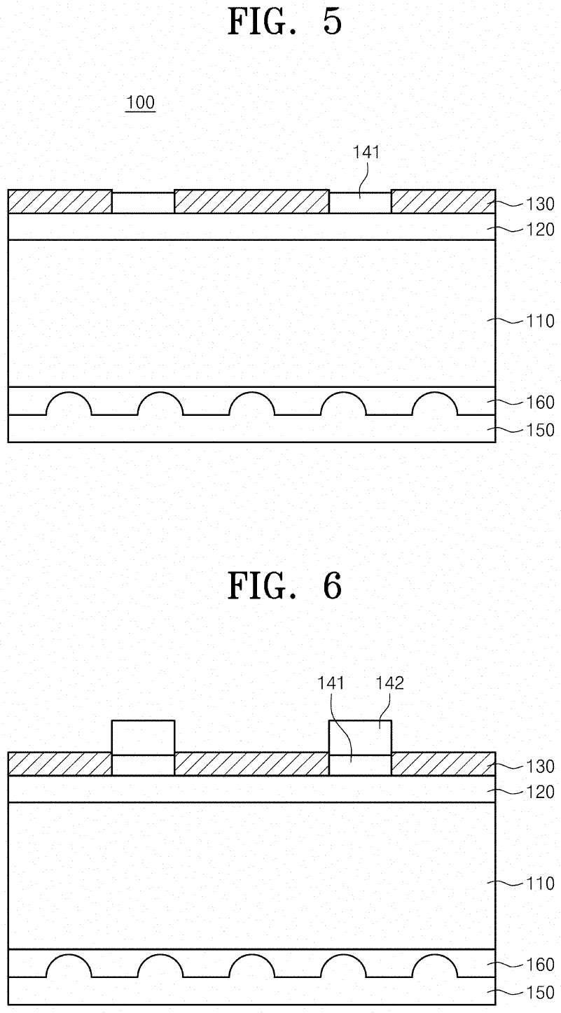

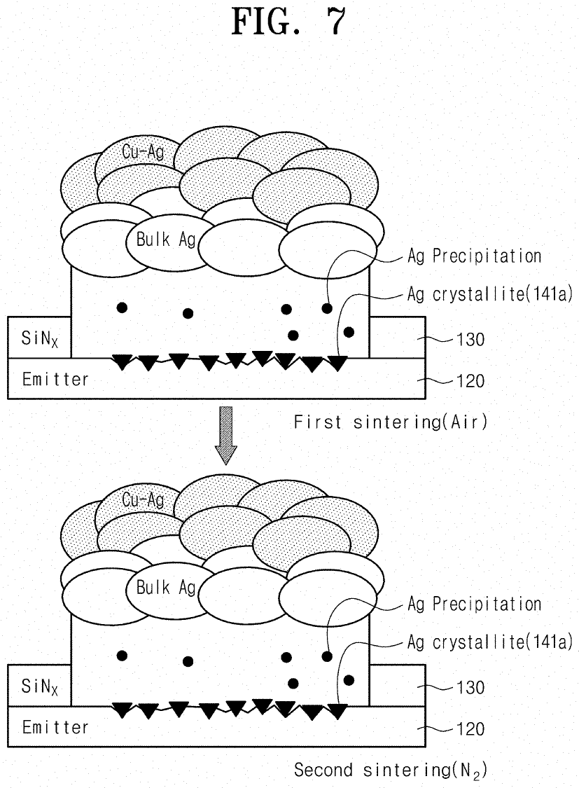

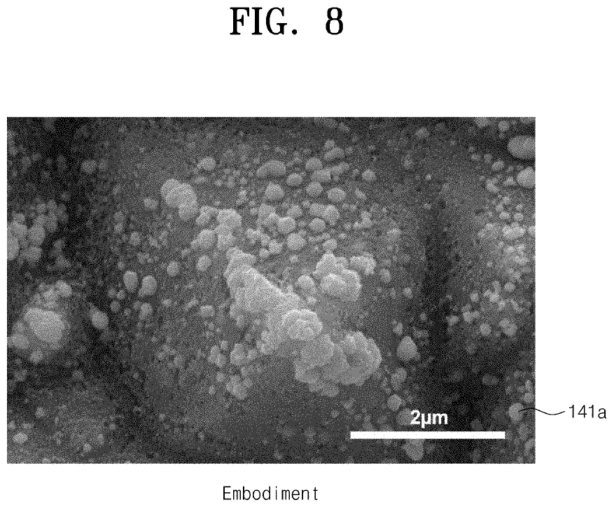

FIG. 4 is a flowchart illustrating a method for manufacturing the solar cell according to an embodiment of the present disclosure. FIGS. 5 and 6 are sectional views sequentially illustrating the manufacturing process according to a flow of FIG. 4. FIGS. 7 and 8 are an exemplary view and an electronic microscopic image illustrating characteristics of the electrode manufactured according to an embodiment of the present disclosure.

Hereinafter, the method for manufacturing the solar cell according to an embodiment of the present disclosure will be described with reference to FIGS. 4 to 8.

The method for manufacturing the solar cell according to an embodiment of the present disclosure may include a first printing operation S10, a first sintering operation S20, a second printing operation S30, and a second sintering operation S40.

In the first printing operation S10, first, as described above, the solar cell before the front electrode 140 is formed is prepared.

Here, the rear electrode 150 and the rear electric field layer 160 may not be formed before the front electrode 140 is formed, but a detailed description of the configuration of the solar cell 100, except for the front electrode 140, will be omitted hereinafter.

In the first printing operation S10, the first paste is printed on the reflection preventing film 130 by using the first screen mask (not illustrated).

Meanwhile, although not illustrated, an exposure area (not illustrated), in which the emitter layer 120 is exposed, may be formed in the reflection preventing film 130, and the first paste may be printed in the exposure area by using the first screen mask (not illustrated).

As described above, the first paste may be formed of the silver (Ag) paste.

Referring to FIG. 5, in the first sintering operation S20, the first electrode layer 141 may be formed on the emitter layer 120 by performing a sintering procedure for 3 minutes at about 800 degrees Celsius.

Then, in the heat treatment process of sintering, the front electrode 140 is connected to the emitter layer 120 through a fire through phenomenon, in which the reflection preventing film 130 is penetrated by a medium of glass frit while the silver contained in the paste for the front electrode 140 is changed to a liquid state at a high temperature and is crystallized to a solid state again through a heat treating process of the front electrode 140.

Here, the first sintering operation S20 may be performed in an air or oxygen atmosphere.

Referring to FIGS. 7 and 8, a plurality of silver (Ag) crystallites 141a may be formed in an etch pit formed on an interface of the emitter layer 120.

Here, the silver (Ag) crystallites may be generated through an oxidation/reduction reaction. A material called glass frit (PbO, TeO2, etc.) is contained in the electrode paste, and a phase of the glass is changed to a molten glass form at a specific temperature, and then, an oxidation/reduction reaction of PbO in an interior of molten glass and SiNx on a surface of the substrate occurs whereby SiNx is etched and Pb is generated.

Then, the generated Pb constitutes an alloy with Ag, and helps Ag to be sintered in the molten glass. Furthermore, TTS, Ag is generated in the sintering process, Ag+ and SiNx fused in the molten glass may form silver (Ag) crystallites through an oxidation/reduction reaction with an Si emitter of the emitter layer 120 at the etched part.

The silver (Ag) crystallites 141a may be formed in the emitter layer, and may move the electrons generated in the solar cell to the electrode through direct contact with the electrode or tunneling and collect the electrons.

Meanwhile, as described above, the silver (Ag) crystallites 141a may be generated at a site, at which the Si emitter is etched, in a pure form. For sintering parameters, various mechanisms are currently suggested, and the representative mechanisms include a mechanism that generates electrons by etching much Si as the electrons generated by oxidizing Si and Ag+ positive ions generated in an interior of the molten glass reach each other, and a mechanism that generates many Ag crystallites when many Ag+ positive ions are generated in the interior of the molten glass.

Thereafter, in the second printing operation S30, the second paste is printed on the first electrode layer 141 and the reflection preventing film 130 by using the second screen mask (not illustrated).

As described above, the second paste may include a copper (core)-silver (Ag) paste.

Referring to FIG. 6, in the second sintering operation S40, the second electrode layer 142 may be formed on the first electrode layer 141 by performing the sintering procedure for 3 minutes at about 800 degrees Celsius and the bus bar electrode 143 may be formed on the reflection preventing film 130.

Here, the second sintering operation S40 may be performed in an inert gas atmosphere. In a detailed example, the second sintering operation S40 may be performed in a nitrogen atmosphere.

Referring to FIGS. 7 and 8, accordingly, this may be maintained while the plurality of silver (Ag) crystallites formed in the first sintering operation S20 are not reduced.

Accordingly, when the sintering is further progressed in a nitrogen atmosphere in the second sintering operation S40, the generated existing silver (Ag) crystallites 141a may fail to be melted in the interior of the glass layer and, as a result, may not be reduced. Here, the nitrogen atmosphere may be defined as a state, in which oxygen is completely blocked. That is, it is apparent that the second sintering operation may be performed in an inert gas atmosphere that is an environment, in which oxygen is blocked, as well as in a nitrogen atmosphere.

Meanwhile, when the second sintering operation S40 is performed in an oxygen atmosphere through heat treatment, the generated existing silver (Ag) crystallites 141a may be supplied with oxygen to be melted and may not be generated again later.

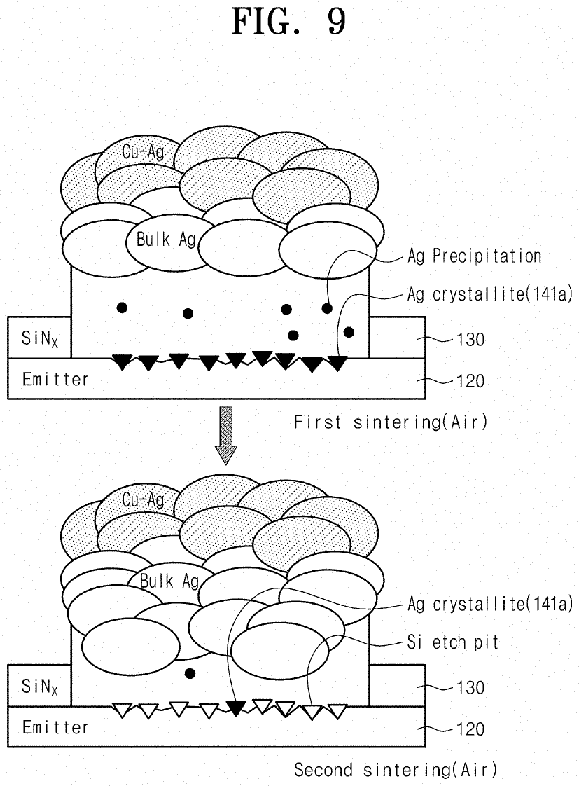

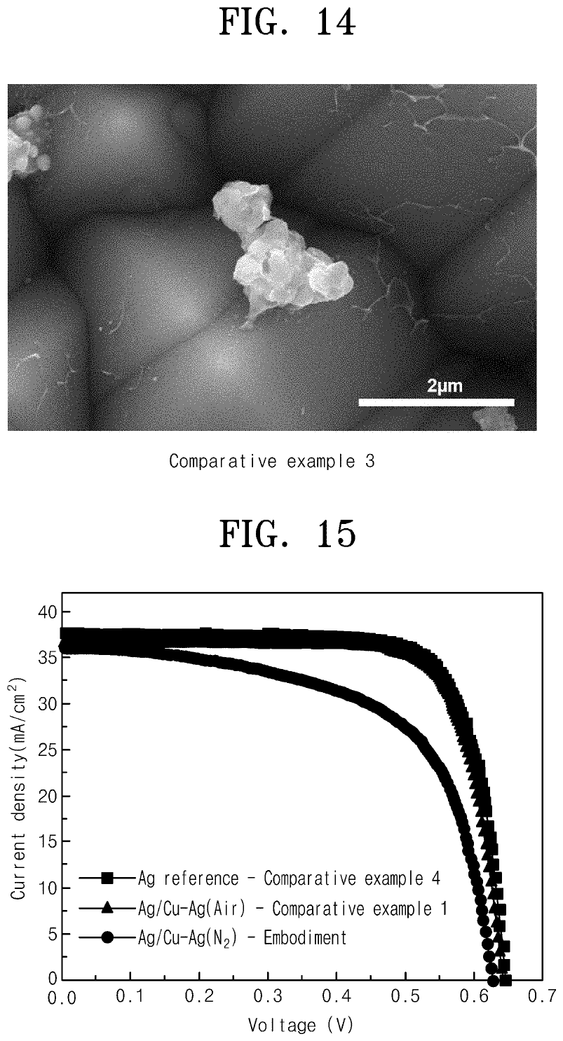

FIGS. 9 to 14 are exemplary views and electronic microscopic images illustrating characteristics of the electrodes manufactured according to comparative examples 1 to 3 of the present disclosure. FIG. 15 is a graph depicting IV results of solar cells according to an embodiment, comparative example 1, and comparative example 4 of the present disclosure.

Hereinafter, electrode structures of the embodiment and the comparative examples, and characteristics thereof will be compared with reference to Table 1, and FIGS. 7 to 15.

TABLE 1

| | | Comparative | Comparative | Comparative | Comparative |
|---|---|---|---|---|---|
| | Embodiment | example 1 | example 2 | example 3 | example 4 |
| Features | Separate | Separate | Simultaneous | Simultaneous | Single |
| | sintering | sintering | sintering | sintering | electrode layer |
| First | Ag paste | Ag paste | Ag paste | Ag paste | Ag paste |
| printing | | | | | |
| First | Air atmosphere | Air atmosphere | — | — | Air atmosphere |
| sintering | | | | | |
| Second | Copper (core)- | Copper (core)- | Copper (core)- | Copper (core)- | — |
| printing | silver (shell) paste | silver (shell) paste | silver (shell) paste | silver (shell) paste | |
| second | Nitrogen | Air atmosphere | Air atmosphere | Nitrogen | — |
| sintering | atmosphere | | | atmosphere | |

First, referring to FIGS. 7 and 8, according to the electrode of the solar cell formed according to the embodiment of the present disclosure, it may be identified that the plurality of silver (Ag) crystallites 141a are formed by performing the first sintering in an oxygen atmosphere after the first printing (the Ag paste) and the second sintering is performed in a nitrogen atmosphere after the second printing (the Cu—Ag paste) whereby the plurality of formed silver (Ag) crystallites 141a are not reduced for maintenance.

Furthermore, referring to FIGS. 9 and 10, according to the electrode of the solar cell formed according to comparative example 1, it may be identified that the plurality of silver (Ag) crystallites 141a are formed by performing the first sintering in an oxygen atmosphere after the first printing (the Ag paste), but the second sintering is performed in an oxygen atmosphere after the second printing (the Cu—Ag paste) whereby the plurality of formed silver (Ag) crystallites 141a are reduced.

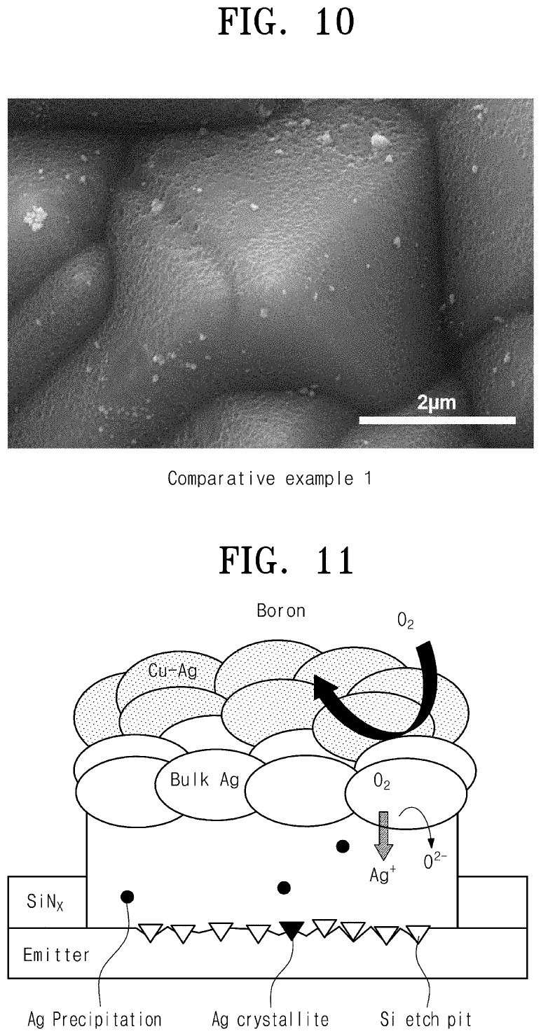

Furthermore, referring to FIGS. 11 and 12, according to the electrode of the solar cell formed according to comparative example 1, the second printing (the Cu—Ag paste) is performed after the first printing (the Ag paste) and the simultaneous sintering is performed in an oxygen atmosphere after the first paste and the second paste are simply laminated, and accordingly, it may be identified that an amount of the formed silver (Ag) crystallites 141a is very small.

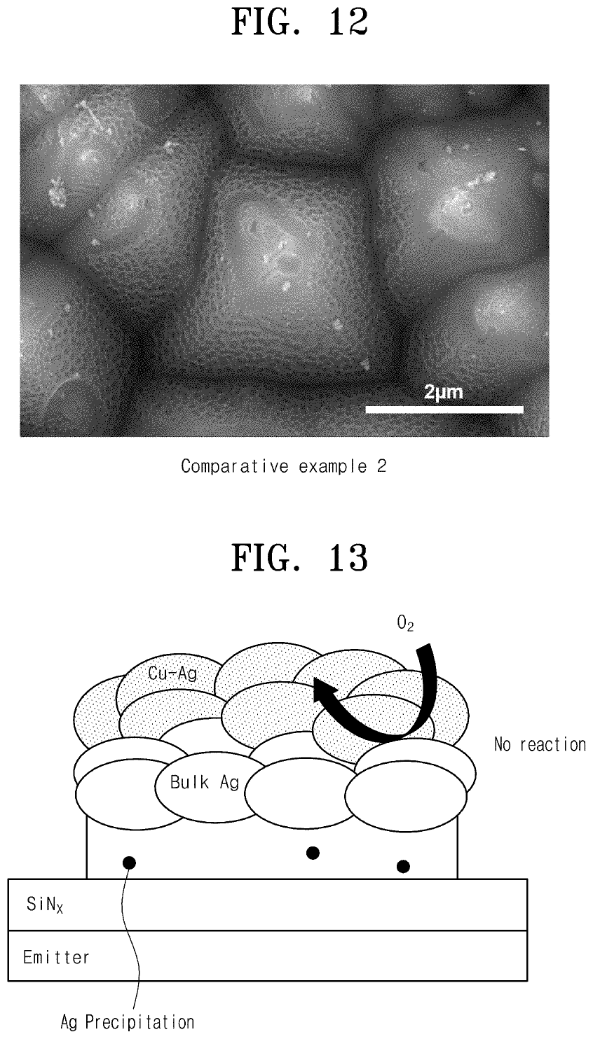

Furthermore, referring to FIGS. 13 and 14, according to the electrode of the solar cell formed according to comparative example 3, the second printing (the Cu—Ag paste) is performed after the first printing (the Ag paste), and the simultaneous sintering is performed in a nitrogen atmosphere after the first paste and the second paste are simply laminated, and accordingly, it may be identified that there is no reaction, in which etch pits and silver (Ag) crystallites are formed on an interface of the emitter layer 120 and only silver (Ag) precipitations are formed.

Meanwhile, comparative example 1 relates to an electrode of a conventional solar cell, and a finger electrode is formed through the silver paste and is sintered.

Referring to FIG. 15, according to the electrode manufactured according to the embodiment of the present disclosure, a first layer and a second layer may be distinguished by using two different pastes, but it may be identified that electrical characteristics thereof are maintained while not being degraded as compared with the conventional electrode (comparative example 4).

Meanwhile, according to the electrode manufactured according to comparative example 2, the first layer and the second layer may be distinguished by using two different pastes, it may be identified that the electrical characteristics are degraded as compared with the electrode according the embodiment and the conventional electrode.

This is because the silver (Ag) crystallites formed on a surface of the emitter layer 120 function to deliver the electrons generated in the solar cell and collect them.

The above detailed description exemplifies the present disclosure. Furthermore, the above-described contents have been described with the preferred embodiments of the present disclosure, and the present disclosure may be used in various different combinations, modifications, and environments. That is, the present disclosure may be modified and corrected within a scope of the concept of the invention disclosed in the specification, an equivalent scope to the disclosed contents of the writings, and/or a scope of a technology or knowledge of an ordinary person. The written embodiments describe a best state for implementing the technical spirit of the present disclosure, and various modifications required in detailed application fields and purposes of the present disclosure are possible. Accordingly, the above detailed description of the present disclosure corresponds to a disclosed embodiment state, and is not intended to restrict the present disclosure. Furthermore, the attached claims should be construed as including other embodiments.

### DESCRIPTION OF REFERENCE NUMERALS

100: solar cell
110: semiconductor substrate
120: emitter layer
130: reflection preventing film
140: front electrode
141: first electrode layer

1. A method for manufacturing a solar cell by forming electrodes on a semiconductor substrate, the method comprising:
a first printing operation of printing a first paste on the semiconductor substrate;
a first sintering operation of forming a first electrode layer by sintering the first paste;
a second printing operation of printing a second paste on the first electrode layer; and
a second sintering operation of forming a second electrode layer by sintering the second paste.

2. The method of claim 1, wherein the first paste is an Ag paste, and
wherein the second paste is a Cu (core)-Ag (shell) paste.

3. The method of claim 2, wherein the first sintering operation is performed under an air or oxygen atmosphere, and
wherein the second sintering operation is performed under an inert gas atmosphere.

4. The method of claim 3, wherein the first sintering operation includes:
forming a plurality of Ag crystallites in the first electrode layer.

5. The method of claim 4, wherein the second sintering operation includes:
maintaining the plurality of Ag crystallites formed in the first electrode layer.

6. The method of claim 1, wherein the first paste is printed by using a first screen mask in the first printing operation,
wherein the second paste is printed by using a second screen mask in the second printing operation,
wherein only a finger pattern is formed in the first screen mask, and
wherein the finger pattern and a bus bar pattern are formed in the second screen mask.

7. The method of claim 1, wherein an emitter layer and a reflection preventing layer are formed on the semiconductor substrate, and
wherein the first paste is printed on the emitter layer in the first printing operation.
